(19) United States
(12) Patent Application Publication
(10) Pub. No.: US 2024/0138147 A1
(43) Pub. Date: Apr. 25, 2024

(54) THREE-DIMENSIONAL MEMORY DEVICE WORDLINES WITH REDUCED BLOCKING LAYER DAMAGE

(71) Applicant: Applied Materials, Inc., Santa Clara, CA (US)

(72) Inventors: Jaesoo Ahn, San Jose, CA (US); Jose Alexandro Romero, Scottsdale, AZ (US); Kunal Bhatnagar, Chandler, AZ (US); Mahendra Pakala, Saratoga, CA (US)

(21) Appl. No.: 18/486,576

(22) Filed: Oct. 12, 2023

Related U.S. Application Data
(60) Provisional application No. 63/417,612, filed on Oct. 19, 2022.

(51) Int. Cl. H10B 43/20; H01L 21/02

(52) U.S. Cl. CPC H10B 43/20; H01L 21/0228; H10B 43/35

(57) ABSTRACT

A method includes obtaining a base structure of a three-dimensional (3D) memory device, forming, on the base structure, a blocking layer including a high-k dielectric material, and forming, on the blocking layer, a wordline for the 3D memory device including molybdenum using an atomic layer deposition (ALD) process.

### CROSS-REFERENCE TO RELATED APPLICATION(S)

The present application claims the benefit of U.S. Provisional Application 63/417,612, filed on Oct. 19, 2022 and entitled “FORMATION OF THREE-DIMENSIONAL MEMORY DEVICE REPLACEMENT WORDLINES WITH REDUCED BLOCKING LAYER DAMAGE”, the entire contents of which are incorporated by reference herein.

### TECHNICAL FIELD

Embodiments of the present disclosure generally relate to electronic device fabrication. Particularly, embodiments of the present disclosure relate to three-dimensional (3D) memory device wordlines with reduced blocking layer damage.

### BACKGROUND

An electronic device manufacturing apparatus can include multiple chambers, such as process chambers and load lock chambers. Such an electronic device manufacturing apparatus can employ a robot apparatus in the transfer chamber that is configured to transport substrates between the multiple chambers. In some instances, multiple substrates are transferred together. Process chambers may be used in an electronic device manufacturing apparatus to perform one or more processes on substrates, such as deposition processes and etch processes. For many processes gases are flowed into the process chamber. Electronic devices such as semiconductor devices are manufactured by performing a series of operations that may include deposition, oxidation, photolithography, ion implantation, etch, and so on to form many patterned layers.

### SUMMARY

In accordance with an embodiment, a method is provided. The method includes obtaining a base structure of a three-dimensional (3D) memory device, forming, on the base structure, a blocking layer including a high-k dielectric material, and forming, on the blocking layer, a wordline for the 3D memory device including molybdenum using an atomic layer deposition (ALD) process.

In accordance with an embodiment, a three-dimensional (3D) memory device is provided. The 3D memory device includes a blocking layer, and a wordline including molybdenum disposed on the blocking layer. The blocking layer includes a high-k dielectric material resistant to damage by an atomic layer deposition (ALD) chemistry used to form the molybdenum of the wordline.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 is a diagram of an example portion of a three-dimensional (3D) memory device, in accordance with some embodiments.

FIG. 2 is a diagram of an example deposition process that can be used to form at least a portion of a three-dimensional (3D) memory device, in accordance with some embodiments.

FIGS. 3A-3G are diagrams of an example process flow for forming at least a portion of a three-dimensional (3D) memory device, in accordance with some embodiments.

FIG. 4 is a graph illustrating differences in threshold voltage (Vt) shift in volts (V) after 1000 program/erase (P/E) cycles for various combinations of wordline materials and blocking layer materials, in accordance with some embodiments.

FIG. 5 is a graph illustrating leakage currents in amperes (A) with respect to various combinations of wordline materials and blocking layer materials as a function of equivalent oxide thickness (EOT) in nanometers (nm), in accordance with some embodiments.

FIG. 6 is a diagram illustrating an example portion of a three-dimensional (3D) memory device, in accordance with some embodiments.

FIGS. 7A-7D are flowcharts of example methods for fabricating wordlines of a three-dimensional (3D) memory device with reduced blocking layer damage, in accordance with some embodiments.

### DETAILED DESCRIPTION

In some memory devices, such as not-and (NAND) flash memory device (“NAND memory device), a wordline is a component that is involved in the reading, writing, and erasing of data. NAND memory can be organized into a hierarchical structure that includes blocks, pages, and cells. The cells, which store the data as electrical charges, are the smallest units of data storage in a NAND memory device. These cells are grouped into pages, and pages are further grouped into blocks. A wordline can be used to address and select a specific row of cells in the memory array. In a NAND memory device, each cell is essentially a floating-gate transistor or a charge trapping transistor. The cells may be organized in a grid-like structure, with rows and columns.

In a 3D NAND memory device, the basic principles of operation, including the role of the wordlines, are similar to those in a planar (2D) NAND memory device. However, 3D NAND technology introduces a significant change in the physical architecture of the memory cells. Instead of laying out the memory cells flat on a silicon substrate, a 3D NAND memory device includes a vertically arranged stack of layers of memory cells, effectively creating a 3D structure.

A 3D NAND memory device can include multiple wordlines that extend from an initial layer of the stack of layers to a final layer of the stack of layers. Each wordline can be connected to a respective set of cells (“page”), where each cell of the set of cells is included within a respective layer of the stack of layers. More specifically, a wordline can be connected to a control gate of a cell. The 3D NAND memory device can further include multiple bitlines arranged perpendicular with respect to the wordlines, where each bitline is connected to a respective set of cells (“string”). More specifically, a bitline can be connected to a drain of a cell. The 3D NAND memory device can include additional components, such as a source line, select gates (e.g., source select gate and drain select gate), etc. In some 3D NAND memory devices, wordlines are formed from tungsten (W) and/or titanium nitride (TiN).

Similar to a 2D NAND memory device, to read data from a set of cells (“page”) in a 3D NAND memory device, a read voltage is applied to a wordline that is connected to the set of cells, and the data is read out via the connected bitlines. To write or program data onto the set of cells, data is placed on the bitlines and a program voltage is applied to the wordline, which causes electrons to tunnel into a floating gate or charge trap layer of the cell (depending on the specific type of 3D NAND memory device). Erasing data is performed by applying an erase voltage to the substrate that is sufficient high to release the stored charge. Accordingly, read and program operations are performed on a page-level, while erase operations are performed on a block-level.

In some embodiments, a 3D NAND memory device includes a blocking layer. The blocking layer acts as a barrier that prevents electrons, which are stored in a charge storage layer of a cell (e.g., floating gate or charge trap layer), from leaking out. In doing so, the blocking layer acts as an insulator to help to maintain the stored charge. For example, a blocking layer can be formed from a dielectric material. One example of a dielectric material used to form blocking layers is aluminum oxide (Al₂O₃). Al₂O₃ is a dielectric material having a dielectric constant of about 7.8. Accordingly, the blocking layer can contribute to the overall reliability and performance of the cell by ensuring that the charge stored in the cell remains stable and unaffected by disturbances from neighboring cells or external factors. The blocking layer can also act as a barrier that prevents impurities such, e.g., as chlorine and fluorine from diffusing into the charge storage layer.

As discussed above, during program and erase operations, charge moves into and out of the charge storage layer through a process called tunneling. The blocking layer, in concert with a tunnel layer, may control this tunneling process. The tunnel layer is a thin insulating layer that separates a channel layer from the charge storage layer, where the data is stored in the form of electrical charge. The primary function of the channel layer is to serve as the conduction path for the flow of electrical current through the memory cells during read, program and erase operations. In essence, the channel layer connects the source and drain regions of the memory cell transistors, allowing current to flow through them when the appropriate voltages are applied. For example, during programming, electrons can tunnel through the tunnel layer via the channel layer and get trapped in the charge storage layer. During erasing, electrons can tunnel back through the tunnel layer and exit through the channel layer.

In some embodiments, the 3D NAND memory device includes a charge blocking layer. The charge blocking layer may be used, for example, in charge trap flash (CTF) memory cells. In traditional floating-gate flash memory cells, data is stored by injecting electrons into a conductive floating gate. In contrast, CTF memory cells use a charge trap layer to store the electrons, and this charge trap is insulated by surrounding dielectric materials, one of which is the charge blocking layer. The charge blocking layer may act as a barrier that prevents electrons, which are stored in the charge trap layer, from leaking out into the control gate or other surrounding materials.

The change from a planar 2D architecture to a 3D vertically stacked architecture can enable significant advantages, including higher capacity, better performance, and lower power consumption. One benefit of 3D NAND is that it allows for significant scaling and increased storage density without requiring the cells to shrink in size. This is done by increasing the number of layers in the stack.

The number of layers of cells of 3D memory devices continues to increase to improve storage density. To compensate for the total thickness of memory cells as the number of memory cell layers increase, wordline pitch (e.g., vertical pitch) and thickness can be scaled down in order to reduce the aspect ratio of the vertical channel structure of 3D NAND memory devices. Moreover, wordline resistance and/or resistivity is increasing due to reduced wordline thickness. Accordingly, materials used to form wordlines that can achieve lower resistance or resistivity at thinner thicknesses than W and/or TiN may be beneficial to continue scaling down wordline pitch as the number of memory cell layers increases.

In some embodiments, one candidate to replace W and/or TiN as a wordline material is molybdenum (Mo). For example, Mo has low resistance or resistivity properties and can be formed with reduced barrier thickness (e.g., barrier-less) deposition. Mo may be deposited to form a wordline using any suitable deposition process. One such deposition process is an atomic layer deposition (ALD) process. However, at least some ALD chemistries used to deposit Mo during an ALD process (e.g., solid Mo precursors) can contribute to blocking layer damage (e.g., Al₂O₃ blocking layer damage). Blocking layer damage can negatively affect memory device performance. For example, blocking layer damage can impact threshold voltage shift during program/erase cycles resulting in shorter endurance of a memory device, can negatively impact erase performance due to electron tunneling, etc.

Some approaches to addressing blocking layer damage may involve the use of different nucleation layers or liner layers. However, nucleation layers or liner layers are generally formed from materials with higher resistance or resistivity than the wordline material. Accordingly, approaches that employ nucleation layers or liner layers can increase wordline resistance or resistivity.

To address these and other drawbacks, embodiments described herein relate to the formation of wordlines including Mo with reduced blocking layer damage. More specifically, embodiments described herein can provide for an ALD process to deposit a low resistivity Mo in the formation of wordlines, and can utilize blocking layers formed from high-k dielectric materials that are resistive to damage caused by the ALD chemistry used to form Mo. High-k dielectric materials used to form blocking layers described herein can have a dielectric constant greater than the dielectric constant for Al₂O₃. More specifically, high-k dielectric materials used to form blocking layers described herein can have a dielectric constant greater than about 7.8. For example, high-k dielectric materials used to form blocking layers described herein can have a dielectric constant of greater than or equal to about 10. Thus, embodiments described herein can be used to form 3D memory device wordlines with low resistance and reduced blocking layer damage, which can maintain or improve threshold voltage shift during program/erase cycles. Additionally, forming a wordline from Mo and a blocking layer from high-k dielectric materials can reduce electron tunneling from the wordline to the charge trap layer, which can improve erase performance.

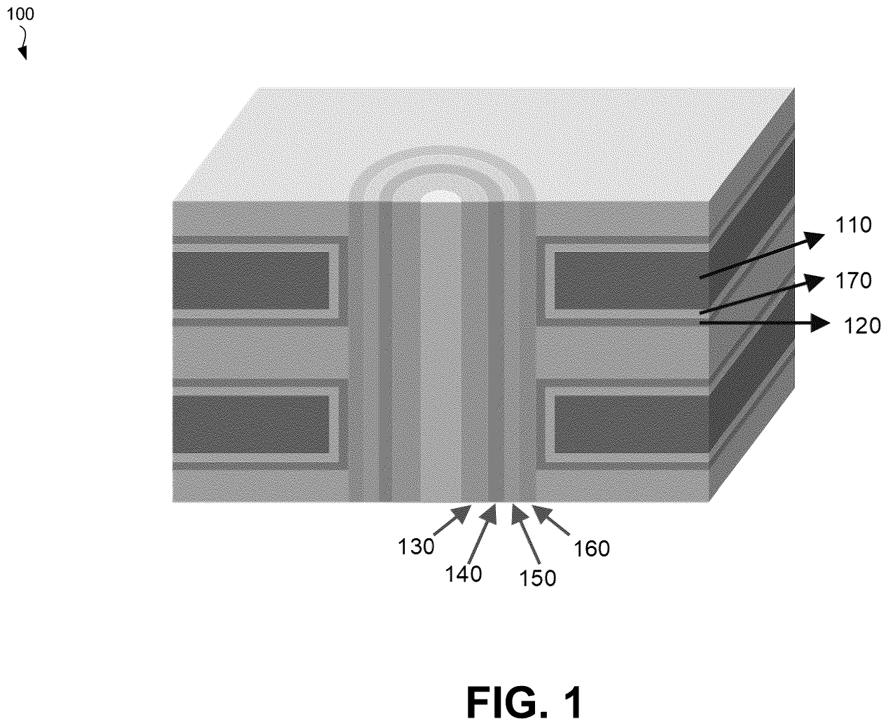

FIG. 1 depicts an example portion of a 3D NAND memory device (“device”) 100, in accordance with some embodiments. The device 100 includes a wordline 110, a blocking layer 120, a channel layer 130, a tunnel layer 140, a charge trap layer 150, and/or a charge blocking layer 160. In this illustrative example, there is no barrier layer (i.e., a barrier-less). In some embodiments, the wordline 110 is a replacement wordline.

In some embodiments, the wordline 110 can include Mo. In some embodiments, the wordline 110 can be formed using an ALD process to deposit Mo in a manner that reduces damage to the blocking layer 120. The ALD process can employ any suitable ALD chemistry. For example, the ALD chemistry can include any suitable ALD Mo precursor(s) and reactant(s). Examples of suitable ALD chemistries include a molybdenum dichloride dioxide (MoO₂Cl₂) precursor or a molybdenum pentachloride (MoCl₅) precursor, and a hydrogen gas (H₂) reactant.

In this example, the device 100 further includes a nucleation layer 170, which can also be referred to as a seed layer. The nucleation layer 170 may be used to form the Mo during an ALD process. The nucleation layer 170 can include any suitable material(s) to promote the formation of Mo during the ALD process. Examples of material(s) that can be used to form the nucleation layer 170 include a molybdenum silicide (MoSix), a molybdenum silicide oxide (e.g., MoSiO), molybdenum nitride (δ-MoN), titanium nitride (TiN), titanium silicon nitride (TiSiN), tantalum nitride (TaN), tantalum silicon nitride (TaSiN), etc. The nucleation layer 170 can be formed using any suitable deposition process. In some embodiments, the nucleation layer 170 is formed using an ALD process. The nucleation layer 170 can be formed to have any suitable thickness. In some embodiments, the thickness of the nucleation layer 170 ranges from about 0.25 nm to about 5 nm. In some embodiments, the thickness of the nucleation layer 170 ranges from about 0.5 nm to about 3 nm.

The blocking layer 120 can include a high-k dielectric material having a dielectric constant greater than Al₂O₃. More specifically, the blocking layer 120 can include a high-k dielectric material having a dielectric constant greater than about 7.8. For example, the blocking layer 120 can include a high-k dielectric material having a dielectric constant of greater than or equal to about 10. In some embodiments, the blocking layer 120 includes a zirconium oxide material. Examples of zirconium oxide materials include zirconium dioxide (ZrO₂), aluminum-zirconium dioxide (AlZrO₂), doped ZrO₂, etc. In some embodiments, the blocking layer 120 includes a lanthanum oxide material. One example of a lanthanum oxide material is lanthanum aluminate (LaAlO₃). In some embodiments, the blocking layer 120 includes a hafnium oxide material. Examples of hafnium oxide materials include hafnium oxide (hafnia) (HfO₂), doped HfO₂, etc. In some embodiments, the blocking layer 120 includes yttrium oxide (yttria) (Y₂O₃). In some embodiments, the blocking layer 120 includes a doped Al₂O₃ material (i.e., Al₂O₃ doped with a high-k material sufficient to increase the dielectric constant of the doped Al₂O₃ material to above about 7.8). The blocking layer 120 can be formed using any suitable deposition process. In some embodiments, the blocking layer 120 is formed using an ALD process. The blocking layer 120 can be formed to have any suitable thickness. In some embodiments, the thickness of the blocking layer 120 ranges from about 1 nm to about 5 nm. In some embodiments, the thickness of the blocking layer 120 ranges from about 2 nm to about 3 nm.

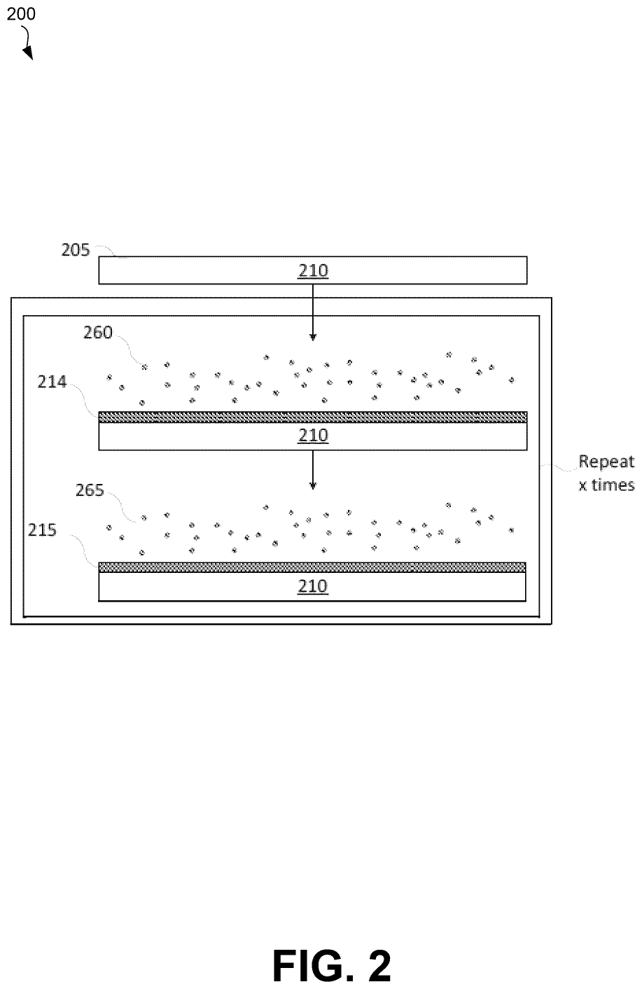

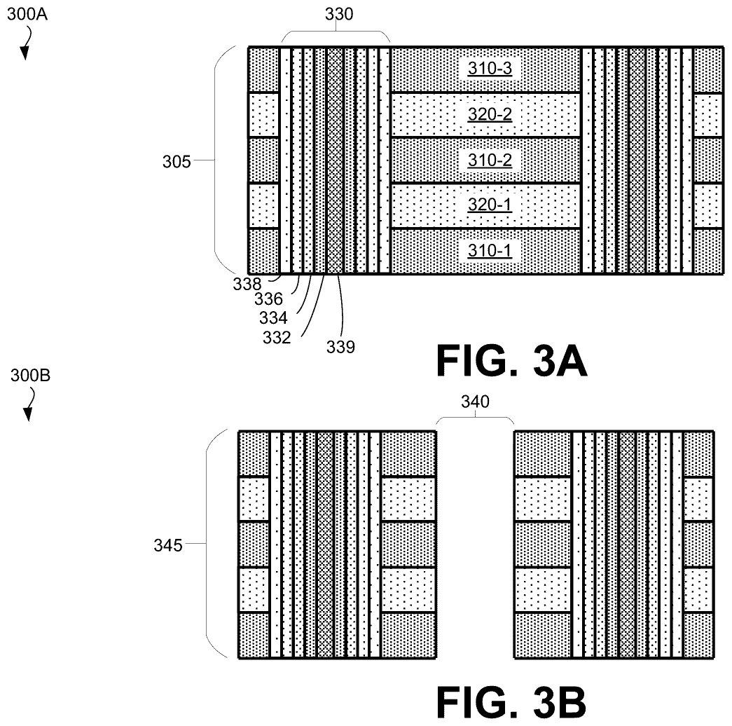

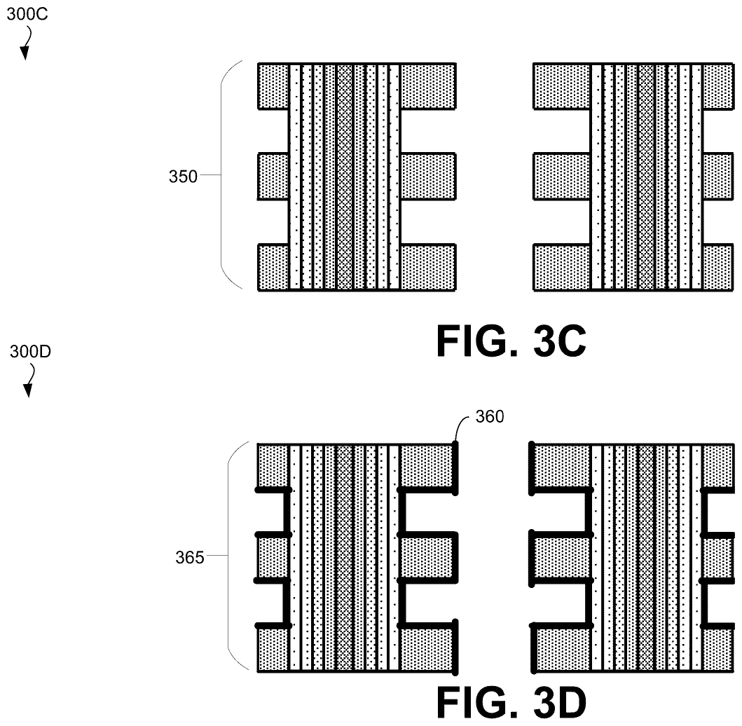

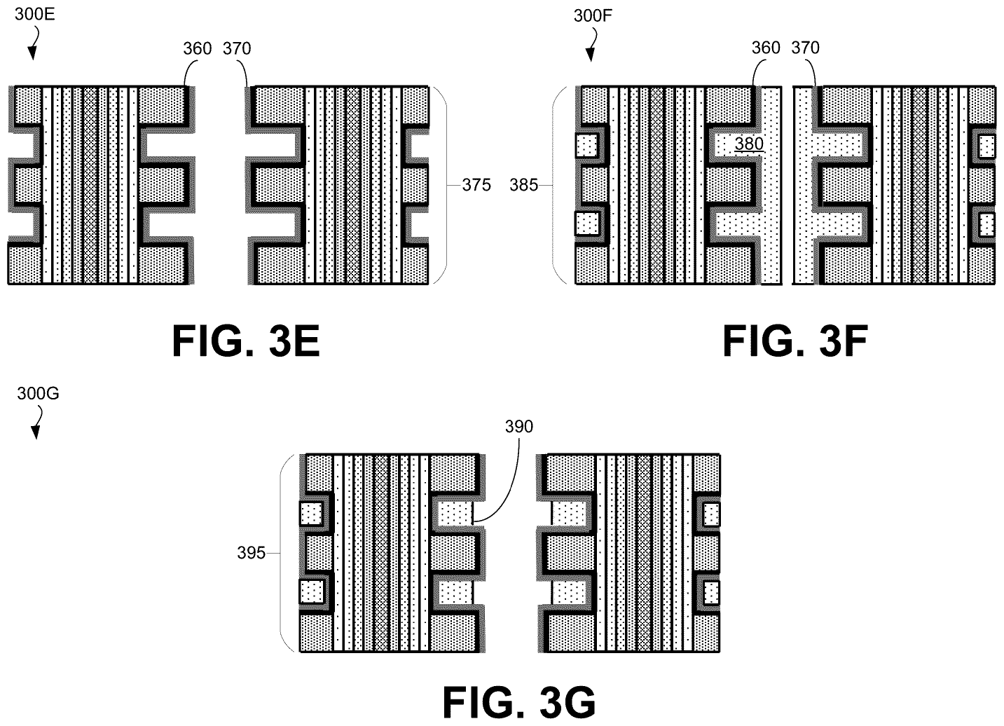

In some embodiments, the channel layer 130 includes silicon (Si). In some embodiments, the tunnel layer 140 includes an oxide material. For example, the tunnel layer 140 can include SiO₂. In some embodiments, the charge trap layer 150 includes a nitride material. For example, the charge trap layer 150 can include a silicon nitride material. In some embodiments, the charge blocking layer 160 includes an oxide material. For example, the charge blocking layer 160 can include SiO₂. Further details regarding the formation of the device 100 will now be described in further detail below with reference to FIGS. 2-3G.

FIG. 2 is a diagram 200 of an example deposition process that can be used to form at least a portion of a 3D memory device, in accordance with some embodiments. In some implementations, the deposition process includes an ALD process. Various types of ALD processes exist, and the specific type may be selected based on several factors such as the surface to be coated, the coating material, chemical interaction between the surface and the coating material, etc. The general principle for the various ALD processes comprises growing a thin film layer by repeatedly exposing the surface to be coated to sequential alternating pulses of gaseous chemical precursors and reactants that chemically react with the surface one at a time in a self-limiting manner.

FIG. 2 illustrates an article 210 having a surface 205. Article 210 may represent a partially formed memory cell of a 3D NAND device. The article 210 and surface 205 may include a blocking layer already formed thereon (not shown) in embodiments. Each individual chemical reaction between a precursor or reactant and the surface is known as a “half-reaction.” During each half reaction, a precursor or reactant is pulsed onto the surface for a period of time sufficient to allow the precursor to fully react with the surface. The reaction is self-limiting as the precursor will only react with a finite number of available reactive sites on the surface, forming a uniform continuous adsorption layer on the surface. Any sites that have already reacted with a precursor will become unavailable for further reaction with the same precursor unless and/or until the reacted sites are subjected to a treatment that will form new reactive sites on the uniform continuous coating. Exemplary treatments may be plasma treatment, treatment by exposing the uniform continuous adsorption layer to radicals, or introduction of a different precursor able to react with the most recent uniform continuous film layer adsorbed to the surface.

In FIG. 2, article 210 having surface 205 may be introduced to a first precursor 260 for a first duration until a first half reaction of the first precursor 260 with surface 205 partially forms layer 215 by forming an adsorption layer 214. Subsequently, article 210 may be introduced to a second precursor 265 (also referred to as a reactant) to cause a second half reaction to react with the adsorption layer 214 and fully form the layer 215. The first precursor 260 may be a precursor for molybdenum, for example. The second precursor 265 may be a hydrogen precursor or reactant, for example. The article 210 may alternately be exposed to the first precursor 260 and second precursor 265 up to x number of times to achieve a target thickness for the layer 215. X may be an integer from 1 to 100, for example.

ALD processes may be conducted at various temperatures depending on the type of ALD process. The optimal temperature range for a particular ALD process is referred to as the “ALD temperature window.” Temperatures below the ALD temperature window may result in poor growth rates and non-ALD type deposition. Temperatures above the ALD temperature window may result in thermal decomposition of the article or rapid desorption of the precursor. The ALD temperature window may range from about 20° C. to about 600° C. In some embodiments, the ALD temperature window is between about 150-350° C.

The ALD process allows for conformal film layers having uniform film thickness on articles and surfaces having complex geometric shapes, holes with large aspect ratios, and three-dimensional structures. Sufficient exposure time of the precursor to the surface enables the precursor to disperse and fully react with the surface in its entirety, including all of its three-dimensional complex features. The exposure time utilized to obtain conformal ALD in high aspect ratio structures is proportionate to the square of the aspect ratio and can be predicted using modeling techniques. Additionally, the ALD technique is advantageous over other commonly used coating techniques because it allows in-situ on demand material synthesis of a particular composition or formulation without lengthy and difficult fabrication of source materials (such as powder feedstock and sintered targets).

FIGS. 3A-3G are diagrams of an example process flow for forming at least a portion of a 3D memory device, in accordance with some embodiments. FIG. 3A shows a diagram 300A of an initial structure 305. The initial structure 305 includes a stack of alternating dielectric layers that includes dielectric layers 310-1 through 310-3 formed from a first material and dielectric layers 320-1 through 320-2 formed from a second material different from the first material. Although three dielectric layers 310-1 through 310-3 and two dielectric layers 320-1 through 320-2 are shown, the initial structure 305 can include any suitable number of dielectric layers. In some embodiments, the first material includes an oxide material and the second material includes a nitride material. For example, the first material includes a silicon oxide (e.g., SiO₂) and the second material includes a silicon nitride (e.g., Si₃N₄).

The initial structure 305 further includes a channel stack 330 disposed within the stack of dielectric layers. For example, the channel stack 330 can include a channel layer 332, a tunnel layer 334, a charge trap layer 336, a channel layer 338, and a dielectric layer (e.g., silicon oxide) layer 339. The channel layers 332 can be similar to the channel layer 130 of FIG. 1, the tunnel layers 334 can be similar to the tunnel layer 140 of FIG. 1, the charge trap layer 336 can be similar to the charge trap layer 150 of FIG. 1, and the charge blocking layer 338 can be similar to the charge blocking layer 160 of FIG. 1.

FIG. 3B shows a diagram 300B illustrating an etch process performed to form an opening 340 within the initial structure 305 to form an intermediate structure 345. The opening 340 is formed to expose the dielectric layers 320-1 and 320-2, which will subsequently be removed as described below with reference to FIG. 3C. In some embodiments, the opening 340 is a slit and the etch process is a slit etch process. Any suitable etch process can be used to form the opening 340 in accordance with embodiments described herein. In some embodiments, the etch process is a dry etch process. For example, the etch process can be a reactive-ion etch (RIE) process.

FIG. 3C shows a diagram 300C illustrating the removal of the dielectric layers 320-1 and 320-2 to form an intermediate structure 350, also referred to as a base structure. The dielectric layers 320-1 and 320-2 can be removed using any suitable process. In some embodiments, the dielectric layers 320-1 and 320-2 are removed using an etch process that can selectively etch the second material with respect to the first material (e.g., a selective etch process). For example, the etch process can be a wet etch process using a suitable wet etchant.

FIG. 3D shows a diagram 300D illustrating the formation of a blocking layer 360 conformal to exposed surfaces of the base structure 350 to form intermediate structure 365. The blocking layer 360 can be similar to the blocking layer 120 of FIG. 1. The blocking layer 360 can be formed using any suitable deposition process. In some embodiments, the blocking layer 360 is formed using an ALD process. The blocking layer 360 can be formed to have any suitable thickness. In some embodiments, the thickness of the blocking layer 360 ranges from about 1 nm to about 5 nm. In some embodiments, the thickness of the blocking layer 360 ranges from about 2 nm to about 3 nm.

FIG. 3E shows a diagram 300E illustrating the formation of a nucleation layer 370 conformal to the blocking layer 360 of the intermediate structure 365 to form intermediate structure 375. The nucleation layer 370 can be similar to the nucleation layer 170 of FIG. 1. The nucleation layer 370 can be formed using any suitable deposition process. In some embodiments, the nucleation layer 370 is formed using an ALD process. The nucleation layer 370 can be formed to have any suitable thickness. In some embodiments, the thickness of the nucleation layer 370 ranges from about 0.25 nm to about 5 nm. In some embodiments, the thickness of the nucleation layer 370 ranges from about 0.5 nm to about 3 nm.

FIG. 3F shows a diagram 300F illustrating the formation of wordline material 380 within a gap (e.g., lateral gap) of the intermediate structure 375 to form intermediate structure 385. In some embodiments, the wordline material 380 includes Mo. The wordline material 380 can be formed using any suitable deposition process. In some embodiments, the wordline material 380 is formed using an ALD process. The wordline material 380 can be formed to have any suitable thickness. In some embodiments, the thickness of the wordline material 380 ranges from about 5 nm to about 30 nm. The thickness of the wordline material 380 may not exceed the thickness of the opening 340 of FIB. 3B. In some embodiments, the wordline material 380 does not completely fill the lateral gap and leave seam or void within the lateral gap. In some embodiments, the wordline material 380 completely fills the lateral gap without formation of seam or void. In some embodiments, the steps of the process flow shown in FIGS. 3E-3F (e.g., formation of the nucleation layer 370 and formation of the wordline material 380) can be performed without a vacuum break.

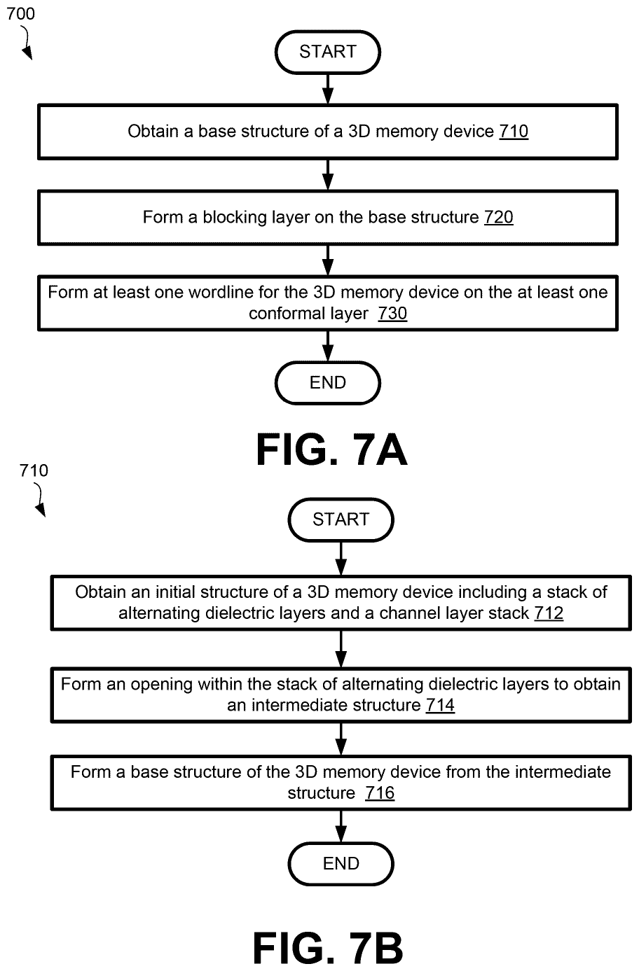

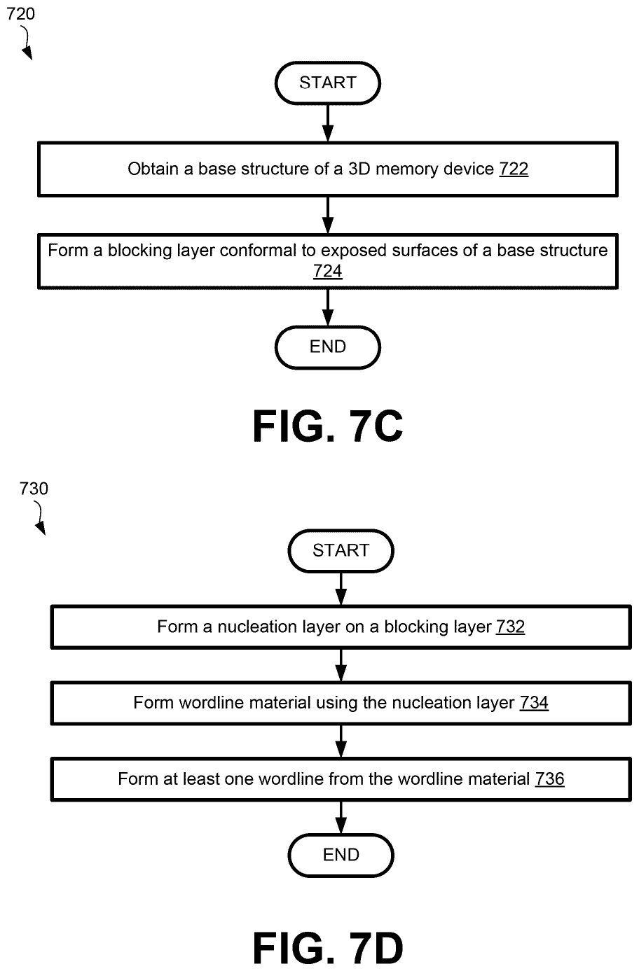

FIG. 3G shows a diagram 300G illustrating the formation wordlines 390 to form structure 395. More specifically, the wordlines 390 can be formed by recessing or etching back the wordline material 380. The wordlines 390 can be formed using any suitable process. In some embodiments, the wordlines 390 are formed by using an isotropic etch process. For example, the isotropic etch process can be a dry etch process or a wet etch process. Further details regarding the process flow shown in FIGS. 3A-3G are described above with reference to FIGS. 1-2 and will be described in further detail below with reference to FIGS. 7-8.

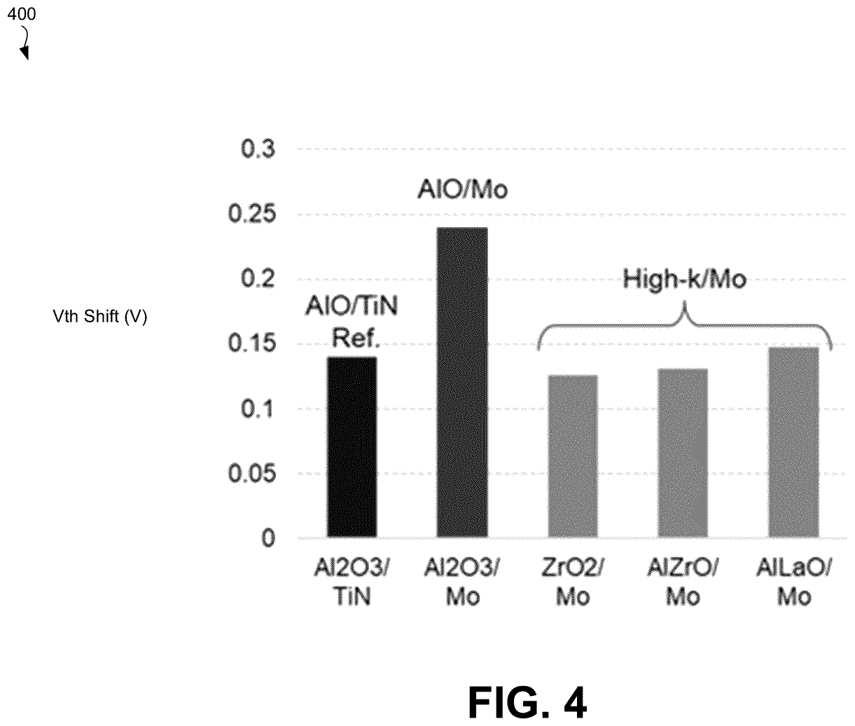

FIG. 4 is a graph 400 illustrating differences in threshold voltage (Vth) shift in volts (V) after 1000 program/erase (P/E) cycles for various combinations of wordline materials and blocking layer materials. As shown, wordlines formed from Mo and blocking layers including a high-k dielectric material (e.g., ZrO₂, AlZrO₂ and LaAlO₃) exhibit improved Vt shift after 1000 P/E cycles as compared to wordlines formed from Mo and blocking layers including Al₂O₃.

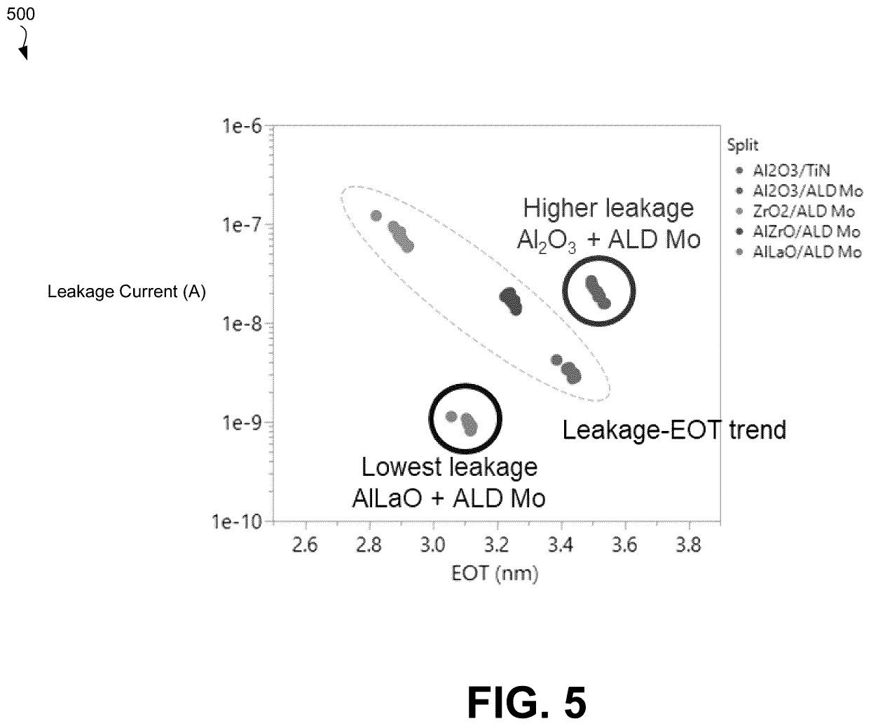

FIG. 5 is a graph 500 illustrating leakage currents in amperes (A) with respect to various combinations of wordline materials and blocking layer materials as a function of equivalent oxide thickness (EOT) in nanometers (nm), in accordance with some embodiments. EOT can refer to the thickness of a silicon oxide (SiO₂) layer that would provide the same electrical performance as that of the high-k dielectric material being used to form a blocking layer (e.g., blocking layer 120 of FIG. 1).

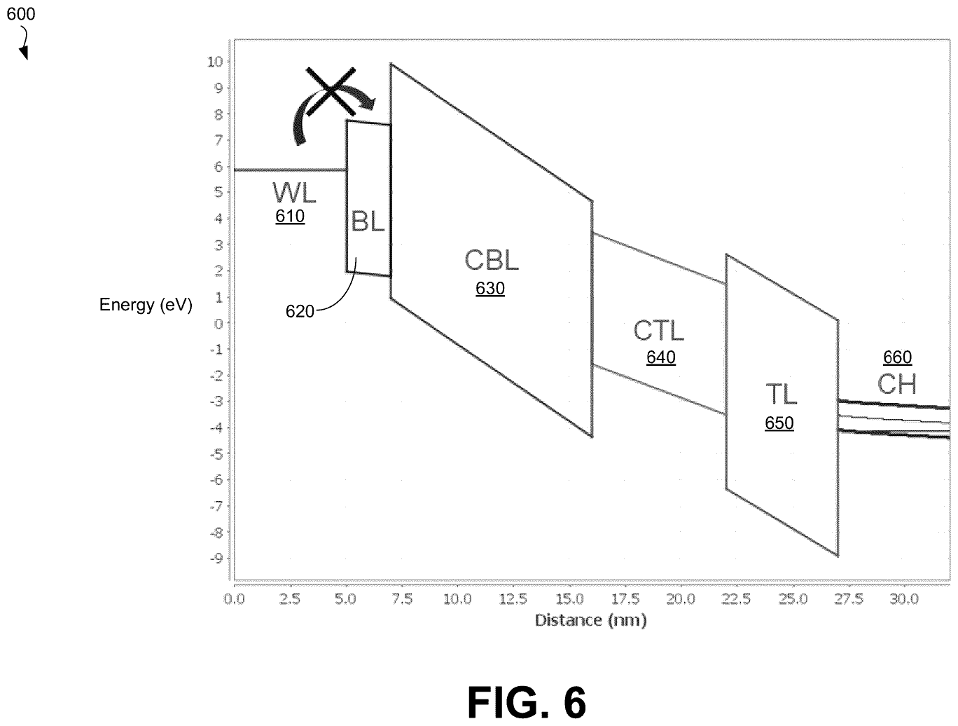

FIG. 6 is a diagram 600 illustrating an example portion of a 3D memory device, in accordance with some embodiments. The 3D memory device can include a number of components including a wordline (WL) 610, a blocking layer (BL) 620, a charge blocking layer (CBL) 630, a charge trap layer (CTL) 640, a tunnel layer (TL) 650, and a channel layer (CH) 650. More specifically, the wordline 610 can include Mo and the blocking layer 620 can include a high-k dielectric material as described above. The diagram illustrates electron energy (eV), and a distance in nanometers (nm) with respect to the components of the 3D memory device. The arrow with the “X” through it indicates that electron tunneling from the wordline 610 to the charge trap layer 640 can be reduced due to the combination of the wordline 610 including Mo and the blocking layer 420 including the high-k dielectric material, which can improve erase performance.

FIG. 7A is a flowchart of a method 700 for fabricating three-dimensional (3D) wordlines with reduced blocking layer damage, in accordance with some embodiments. At block 710, a base structure of a 3D memory device is obtained. The base structure can include multiple components. In some embodiments, the base structure includes a channel layer, a tunnel layer, a charge trap layer and a charge blocking layer. In some embodiments, obtaining the base structure includes forming at least one component of the base structure. For example, obtaining the base structure can include forming at least one of the channel layer, the tunnel layer, the charge trap layer or the charge blocking layer. Further details regarding obtaining the base structure are described above with reference to FIGS. 1 and 3A-3C and will be described in further detail below with reference to FIG. 7B.

At block 720, a blocking layer is formed on the base structure. In some embodiments, the blocking layer is formed directly on the base structure. For example, the blocking layer can be a conformal layer. The blocking layer can be formed of a high-k dielectric material that resists damage to a chemistry used to form at least one wordline (e.g., ALD chemistry). In some embodiments, the blocking layer is formed of a high-k dielectric material that resists damage to a chemistry used to form Mo. Further details regarding forming the blocking layer are described above with reference to FIGS. 1 and 3D and will be described in further detail below with reference to FIG. 7C.

At block 730, at least one wordline for the 3D memory device is formed on the blocking layer. In some embodiments, the at least one wordline includes a replacement wordline. In some embodiments, the at least one wordline is formed from Mo. Further details regarding forming the at least one wordline on the blocking layer are described above with reference to FIGS. 1 and 3D and will be described in further detail below with reference to FIG. 7D.

FIG. 7B is a flowchart of a method 710 for obtaining a base structure of a 3D memory device, in accordance with some embodiments. At block 712, an initial structure of a 3D memory device including a stack of alternating dielectric layers and a channel layer stack is obtained. More specifically, the stack of alternating dielectric layers can include at least one first dielectric layer formed from a first material and at least one second dielectric layer formed from a second material different from the first material. In some embodiments, the first material includes an oxide material and the second material includes a nitride material. For example, the first material includes a silicon oxide (e.g., SiO₂) and the second material includes a silicon nitride (e.g., Si₃N₄). The channel stack can include a channel layer, a tunnel layer, a charge trap layer and a channel layer.

At block 714, an opening is formed within the stack of alternating dielectric layers to obtain an intermediate structure. Forming the opening can include performing an etch process. The opening is formed to expose the at least one second dielectric layer of the stack of alternating dielectric layers. In some embodiments, the opening is a slit and the etch process is a slit etch process. Any suitable etch process can be used to form the opening in accordance with embodiments described herein. In some embodiments, the etch process is a dry etch process. For example, the etch process can be an RIE process.

At block 716, a base structure of the 3D memory device is formed from the intermediate structure. Forming the base structure can include removing the at least one second dielectric layer. The at least one second dielectric layer can be removed using any suitable process. In some embodiments, the at least one second dielectric layer is removed using an etch process that can selectively etch the second material with respect to the first material (e.g., a selective etch process). For example, the etch process can be a wet etch process using a suitable wet etchant. Further details regarding blocks 712-716 are described above with reference to FIGS. 1, 3A-3C and 7A.

FIG. 7C is a flowchart of a method 720 for forming a blocking layer on a base structure of a 3D memory device, in accordance with some embodiments. At block 722, a base structure of a 3D memory device is obtained. For example, the base structure can be the base structure obtained at block 710 of FIG. 7A (e.g., blocks 710-716 of FIG. 7B).

At block 724, a blocking layer is formed conformal to exposed surfaces of a base structure of a 3D memory device. The blocking layer can be formed using any suitable deposition process. In some embodiments, the blocking layer is formed using an ALD process. The blocking layer can be formed to have any suitable thickness. In some embodiments, the thickness of the blocking layer ranges from about 1 nm to about 5 nm. In some embodiments, the thickness of the blocking layer ranges from about 2 nm to about 3 nm.

The blocking layer can be formed of a high-k dielectric material that resists damage to the ALD chemistry used to form a wordline material used to form a wordline of the 3D memory device. In some embodiments, the wordline material includes Mo. The blocking layer can include a high-k dielectric material having a dielectric constant greater than Al₂O₃. More specifically, the blocking layer can include a high-k dielectric material having a dielectric constant greater than about 7.8. For example, the blocking layer can include a high-k dielectric material having a dielectric constant of greater than or equal to about 10. In some embodiments, the blocking layer includes a zirconium oxide. Examples of zirconium oxide materials include ZrO₂, AlZrO₂, doped ZrO₂, etc. In some embodiments, the blocking layer includes a lanthanum oxide. One example of a lanthanum oxide is LaAlO₃. In some embodiments, the blocking layer includes a hafnium oxide. Examples of hafnium oxides include HfO₂, doped HfO₂, etc. In some embodiments, the blocking layer includes Y₂O₃. In some embodiments, the blocking layer includes a doped Al₂O₃ (i.e., Al₂O₃ doped with a high-k material sufficient to increase the dielectric constant of the doped Al₂O₃ material to above about 7.8). Further details regarding blocks 722-724 are described above with reference to FIGS. 1, 3A-3D and 7A.

FIG. 7D is a flowchart of a method 730 for forming at least one wordline on a blocking layer, in accordance with some embodiments. For example, the blocking layer can be the blocking layer formed at block 720 of FIG. 7A (e.g., blocks 722-724 of FIG. 7C).

At block 732, a nucleation layer is formed on the blocking layer. More specifically, the nucleation layer can be formed conformal to the blocking layer. The nucleation layer can be used to promote the formation of wordline material at block 734. The nucleation layer can be formed using any suitable deposition process. In some embodiments, the nucleation layer is formed using an ALD process. The nucleation layer can be formed to have any suitable thickness. In some embodiments, the thickness of the nucleation layer ranges from about 0.25 nm to about 5 nm. In some embodiments, the thickness of the nucleation layer 370 ranges from about 0.5 nm to about 3 nm.

At block 734, wordline material is formed using the nucleation layer. More specifically, the wordline material can be formed within a gap (e.g., lateral gap). In some embodiments, the wordline material includes Mo. The wordline material can be formed using any suitable deposition process. In some embodiments, the wordline material is formed using an ALD process. More specifically, forming the wordline material can include depositing Mo using an ALD process using a suitable ALD chemistry (e.g., MoO₂Cl₂ or MoCl₅ precursor and H₂ reactant). The wordline material can be formed to have any suitable thickness. In some embodiments, the thickness of the wordline material ranges from about 5 nm to about 30 nm. In some embodiments, an opening (e.g., seam or void) is formed within the wordline material to form the at least one wordline. In some embodiments, the wordline material completely fills the gap without the formation of the opening. In some embodiments, the formation of the nucleation layer at block 732 and formation of the wordline material at block 734 can be performed without a vacuum break.

At block 736, at least one wordline is formed from the wordline material. More specifically, the at least one wordline can be formed by recessing or etching back the wordline material. The at least one wordline can be formed using any suitable process. In some embodiments, the at least one wordline is formed by using an isotropic etch process. For example, the isotropic etch process can be a dry etch process or a wet etch process. Further details regarding blocks 732-736 are described above with reference to FIGS. 1, 3E-3G and 7A.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A method comprising:
obtaining a base structure of a three-dimensional (3D) memory device;
forming, on the base structure, a blocking layer comprising a high-k dielectric material; and
forming, on the blocking layer, a wordline for the 3D memory device comprising molybdenum using an atomic layer deposition (ALD) process.

2. The method of claim 1, wherein the blocking layer comprises a high-k dielectric material having a dielectric constant of greater than about 7.8.

3. The method of claim 2, wherein the blocking layer comprises a high-k dielectric material having a dielectric constant of greater than or equal to about 10.

4. The method of claim 1, wherein the blocking layer comprises at least one of: a zirconium oxide, a lanthanum oxide, a hafnium oxide, a yttrium oxide, or a doped aluminum oxide.

5. The method of claim 4, wherein the blocking layer comprises at least one of: zirconium dioxide, aluminum-zirconium dioxide, or doped zirconium dioxide.

6. The method of claim 4, wherein the blocking layer comprises lanthanum aluminate.

7. The method of claim 4, wherein the blocking layer comprises doped hafnium oxide.

8. The method of claim 1, wherein forming the wordline comprises performing the ALD process using a hydrogen gas reactant and a molybdenum precursor selected from the group consisting of: molybdenum dichloride dioxide and molybdenum pentachloride.

9. The method of claim 1, wherein forming the wordline comprises forming a nucleation layer or a seed layer on the blocking layer by exposing the blocking layer to a precursor.

10. The method of claim 9, wherein the nucleation layer or the seed layer comprises at least one of: molybdenum silicide, molybdenum silicide oxide, molybdenum nitride, titanium nitride, titanium silicon nitride, tantalum nitride, or tantalum silicon nitride.

11. The method of claim 1, wherein the high-k dielectric layer is resistant to damage by an ALD chemistry used to form the molybdenum of the wordline.

12. A three-dimensional (3D) memory device comprising:
a blocking layer; and
a wordline comprising molybdenum disposed on the blocking layer, wherein the blocking layer comprises a high-k dielectric material resistant to damage by an atomic layer deposition (ALD) chemistry used to form the molybdenum of the wordline.

13. The 3D memory device of claim 12, wherein the blocking layer comprises a high-k dielectric material having a dielectric constant of greater than about 7.8.

14. The 3D memory device of claim 12, wherein the blocking layer comprises a high-k dielectric material having a dielectric constant of greater than or equal to about 10.

15. The 3D memory device of claim 12, wherein the blocking layer comprises at least one of: a zirconium oxide, a lanthanum oxide, a hafnium oxide, a yttrium oxide, or a doped aluminum oxide.

16. The 3D memory device of claim 15, wherein the blocking layer comprises at least one of:
zirconium dioxide, aluminum-zirconium dioxide, or doped zirconium dioxide.

17. The 3D memory device of claim 15, wherein the blocking layer comprises lanthanum aluminate.

18. The 3D memory device of claim 15, wherein the blocking layer comprises doped hafnium oxide.

19. The 3D memory device of claim 12, further comprising a nucleation layer or a seed layer disposed between the blocking layer and the wordline.

20. The 3D memory device of claim 19, wherein the nucleation layer or the seed layer comprises at least one of: a molybdenum silicide, a molybdenum silicide oxide, molybdenum nitride, titanium nitride, titanium silicon nitride, tantalum nitride, or tantalum silicon nitride.
